(19) United States
(12) Patent Application Publication
(10) Pub. No.: US 2026/0113925 A1
(43) Pub. Date: Apr. 23, 2026

(54) SEMICONDUCTOR DEVICE, MANUFACTURING METHOD THEREOF, AND MEMORY DEVICE

(71) Applicant: Yangtze Memory Technologies Holdings Co., Ltd., Wuhan (CN)

(72) Inventors: Yanhong Wang, Wuhan (CN); Zongliang Huo, Wuhan (CN); Wei Liu, Wuhan (CN); Liang Chen, Wuhan (CN); Zichen Liu, Wuhan (CN); Shiqi Huang, Wuhan (CN); Yaqin Liu, Wuhan (CN); Mengyang Dong, Wuhan (CN)

(21) Appl. No.: 19/091,461

(22) Filed: Mar. 26, 2025

(30) Foreign Application Priority Data
Oct. 21, 2024 (CN) 202411476821.2

(51) Int. Cl. H10B 12/00; H01L 23/00; H01L 25/00; H01L 25/065; H01L 25/18; H10B 80/00

(52) U.S. Cl. CPC H10B 12/30; H10B 12/02; H10B 80/00; H10W 90/00; H10W 80/211; H10W 80/312; H10W 80/327; H10W 90/792

(57) ABSTRACT

According to one aspect of the present disclosure, a semiconductor device is provided. The semiconductor device may include a word line extending along a first direction. The semiconductor device may include a bit line extending along a second direction. The second direction may intersect with the first direction. The semiconductor device may include a first conductive connection structure located between a first surface and the word line. An end of the first conductive connection structure may be connected to the word line, and the first surface and a second surface may be two surfaces of the semiconductor device opposite to each other along the first direction. The semiconductor device may include a second conductive connection structure located between the second surface and the bit line. An end of the second conductive connection structure may be connected to the bit line.

### CROSS-REFERENCE TO RELATED APPLICATIONS

This application claims the benefit of priority to Chinese Application No. 202411476821.2, filed on Oct. 21, 2024, which is incorporated herein by reference in its entirety.

### TECHNICAL FIELD

The present disclosure relates to the field of semiconductor technologies, for example, to a semiconductor device, a manufacturing method thereof, and a memory device.

### BACKGROUND

With the continuous development of science and technology today, the semiconductor devices are widely applied in various electronic devices and electronic products. For example, a dynamic random access memory (DRAM), which is a volatile memory device, is a semiconductor memory device commonly applied in the computers.

### SUMMARY

According to one aspect of the present disclosure, a semiconductor device is provided. The semiconductor device may include a word line extending along a first direction. The semiconductor device may include a bit line extending along a second direction. The second direction may intersect with the first direction. The semiconductor device may include a first conductive connection structure located between a first surface and the word line. An end of the first conductive connection structure may be connected to the word line, and the first surface and a second surface may be two surfaces of the semiconductor device opposite to each other along the first direction. The semiconductor device may include a second conductive connection structure located between the second surface and the bit line. An end of the second conductive connection structure may be connected to the bit line.

In some implementations, the word line may include a plurality of word lines. In some implementations, the first conductive connection structure may include a plurality of first conductive connection structures. In some implementations, the plurality of word lines may be arranged in an array along the second direction and a third direction. In some implementations, the plurality of word lines may be connected to the plurality of first conductive connection structures in a one-to-one correspondence. In some implementations, the third direction may intersect with the second direction and the first direction.

In some implementations, the semiconductor device may include a plurality of first conductive connection lines arranged along the second direction. In some implementations, the first conductive connection lines may extend along the third direction. In some implementations, the first conductive connection lines may be connected to a plurality of first conductive connection structures arranged along the third direction.

In some implementations, the semiconductor device may include a plurality of memory blocks arranged along the third direction. In some implementations, the first conductive connection lines may be connected to the plurality of first conductive connection structures arranged along the third direction in the plurality of memory blocks.

In some implementations, the first conductive connection lines may be located between the first conductive connection structure and the first surface.

In some implementations, along a direction perpendicular to the first direction, a size of an end of two opposite ends of the first conductive connection structure closer to the word line along the first direction may be a first size. In some implementations, along the direction perpendicular to the first direction, a size of an end of two opposite ends of the first conductive connection structure farther from the word line along the first direction may be a second size. In some implementations, the first size may be greater than the second size.

In some implementations, along a direction perpendicular to the first direction, a size of an end of two opposite ends of the first conductive connection structure closer to the word line along the first direction may be a first size. In some implementations, along the direction perpendicular to the first direction, a size of an end of two opposite ends of the first conductive connection structure farther from the word line along the first direction may be a second size. In some implementations, the first size may be smaller than the second size.

In some implementations, the semiconductor device may include a first bonding layer include a first bonding structure. In some implementations, the first bonding layer may be located on a side of two opposite sides of the word line along the first direction that is close to the second surface. In some implementations, the first bonding structure may be coupled to the word line and the bit line.

In some implementations, the semiconductor device may include a third conductive connection structure. In some implementations, two ends of the third conductive connection structure may be respectively connected to the first conductive connection line and the first bonding structure.

In some implementations, the semiconductor device may include a pad structure located on a side of the first conductive connection line that is close to the first surface. In some implementations, the semiconductor device may include a first interconnection structure. In some implementations, the pad structure and the first bonding structure may be connected through the first interconnection structure.

In some implementations, the semiconductor device may include a memory layer including a plurality of word lines, a plurality of bit lines, and a plurality of memory cells. In some implementations, the memory cell may include a capacitor structure and a transistor structure arranged along the third direction. In some implementations, the plurality of memory cells may constitute a plurality of memory cell groups arranged along the third direction. In some implementations, the memory cell group may include a plurality of memory cell subgroups arranged in an array along the first direction and the second direction. In some implementations, the memory cell subgroup may include a first memory cell and a second memory cell arranged along the third direction. In some implementations, one of the word lines may be connected to the first memory cell or the second memory cell of the plurality of memory cell subgroups arranged along the first direction. In some implementations, one of the bit lines may be connected to the first memory cell and the second memory cell of the plurality of memory cell subgroups arranged along the second direction.

In some implementations, the transistor structure may include a semiconductor body extending along the third direction. In some implementations, two ends of the semiconductor body opposite to each other along the third direction may be respectively connected to the bit line and the capacitor structure. In some implementations, the transistor structure may include a gate structure. In some implementations, the gate structure may surround the semiconductor body. In some implementations, a plurality of gate structures arranged along the first direction may be connected to each other to form the word line.

According to another aspect of the present disclosure, a memory device is provided. The memory device may include a first semiconductor structure and a second semiconductor structure stacked along a first direction. The first semiconductor structure may include a peripheral circuit. The second semiconductor structure may include a word line extending along the first direction. The second semiconductor structure may include a bit line extending along a second direction. The second direction may intersect with the first direction. The second semiconductor structure may include a first conductive connection structure located on a side of two opposite sides of the word line along the first direction that is far from the first semiconductor structure. An end of the first conductive connection structure may be connected to the word line.

In some implementations, the second semiconductor structure may further include a second conductive connection structure located between the bit line and the first semiconductor structure. In some implementations, an end of the second conductive connection structure may be connected to the bit line.

In some implementations, the first semiconductor structure may further include a second bonding layer. In some implementations, the second bonding layer may include a second bonding structure. In some implementations, the second bonding layer may be located between the peripheral circuit and the second semiconductor structure. In some implementations, the second semiconductor structure may further include a first bonding layer. In some implementations, the first bonding layer may include a first bonding structure. In some implementations, the first bonding layer may be located between the first semiconductor structure and the word line or the bit line. In some implementations, the second bonding structure may be coupled to the peripheral circuit. In some implementations, the first bonding structure may be coupled to the word line and the bit line. In some implementations, the first bonding structure may be connected to the second bonding structure.

In some implementations, the word line may include a plurality of word lines. In some implementations, the first conductive connection structure may include a plurality of first conductive connection structures. In some implementations, the plurality of word lines may be arranged in an array along the second direction and a third direction. In some implementations, the plurality of word lines may be connected to the plurality of first conductive connection structures in a one-to-one correspondence. In some implementations, the third direction may intersect with the second direction and the first direction.

In some implementations, the second semiconductor structure may further include a plurality of first conductive connection lines arranged along the second direction. In some implementations, the first conductive connection lines may extend along the third direction. In some implementations, the first conductive connection lines may be connected to a plurality of first conductive connection structures arranged along the third direction.

In some implementations, the second semiconductor structure may include a plurality of memory blocks arranged along the third direction. In some implementations, the first conductive connection lines may be connected to the plurality of first conductive connection structures arranged along the third direction in the plurality of memory blocks.

In some implementations, the first conductive connection line and the first bonding layer may be respectively located on the two opposite sides of the word line along the first direction.

In some implementations, along a direction perpendicular to the first direction, a size of an end of two opposite ends of the first conductive connection structure closer to the word line along the first direction may be a first size. In some implementations, along the direction perpendicular to the first direction, a size of an end of two opposite ends of the first conductive connection structure farther from the word line along the first direction may be a second size. In some implementations, the first size may be greater than the second size.

In some implementations, along a direction perpendicular to the first direction, a size of an end of two opposite ends of the first conductive connection structure closer to the word line along the first direction may be a first size. In some implementations, along the direction perpendicular to the first direction, a size of an end of two opposite ends of the first conductive connection structure farther from the word line along the first direction may be a second size. In some implementations, the first size may be smaller than the second size.

In some implementations, the second semiconductor structure may further include a third conductive connection structure. In some implementations, two ends of the third conductive connection structure may be respectively connected to the first conductive connection line and the first bonding structure.

In some implementations, the second semiconductor structure may further include a pad structure. In some implementations, the first conductive connection line may be located between the pad structure and the first conductive connection structure. In some implementations, the second semiconductor structure may further include a first interconnection structure. In some implementations, the pad structure and the first bonding structure are connected through the first interconnection structure.

In some implementations, the second semiconductor structure may include a memory layer including the plurality of word lines, a plurality of bit lines, and a plurality of memory cells. In some implementations, the memory cell may include a capacitor structure and a transistor structure arranged along the third direction. In some implementations, the plurality of memory cells may constitute a plurality of memory cell groups arranged along the third direction. In some implementations, the memory cell group may include a plurality of memory cell subgroups arranged in an array along the first direction and the second direction. In some implementations, the memory cell subgroup may include a first memory cell and a second memory cell arranged along the third direction. In some implementations, one of the word lines may be connected to the first memory cell or the second memory cell of the plurality of memory cell subgroups arranged along the first direction. In some implementations, one of the bit lines may be connected to the first memory cell and the second memory cell of the plurality of memory cell subgroups arranged along the second direction.

In some implementations, the transistor structure may include a semiconductor body extending along the third direction. In some implementations, two ends of the semiconductor body opposite to each other along the third direction may be respectively connected to the bit line and the capacitor structure. In some implementations, the transistor structure may include a gate structure. In some implementations, the gate structure may surround the semiconductor body. In some implementations, a plurality of gate structures arranged along the first direction are connected to each other to form the word line.

According to a further aspect of the present disclosure, a method of manufacturing a semiconductor device is provided. The method may include forming a word line extending along a first direction. The method may include forming a bit line extending along a second direction. The second direction may intersect with the first direction. The method may include forming a first conductive connection structure located between a first surface and the word line. An end of the first conductive connection structure may be connected to the word line. The first surface and a second surface may be two surfaces of the semiconductor device opposite to each other along the first direction. The method may include forming a second conductive connection structure located between the second surface and the bit line. An end of the second conductive connection structure may be connected to the bit line.

In some implementations, the word line may include a plurality of word lines. In some implementations, the first conductive connection structure may include a plurality of first conductive connection structures. In some implementations, the plurality of word lines may be arranged in an array along the second direction and a third direction. In some implementations, the plurality of word lines may be connected to the plurality of first conductive connection structures in a one-to-one correspondence. In some implementations, the third direction may intersects with the second direction and the first direction.

In some implementations, the forming the word line, the bit line, the first conductive connection structure and the second conductive connection structure may include providing a semiconductor layer including a first side and a second side opposite to each other along a thickness direction of the semiconductor layer. In some implementations, the forming the word line, the bit line, the first conductive connection structure and the second conductive connection structure may include forming the first conductive connection structure in the semiconductor layer from the first side. In some implementations, the forming the word line, the bit line, the first conductive connection structure and the second conductive connection structure may include forming the bit line and the word line on the semiconductor layer from the first side. In some implementations, the forming the word line, the bit line, the first conductive connection structure and the second conductive connection structure may include forming the second conductive connection structure on the bit line from the first side.

In some implementations, before forming the first conductive connection structure in the semiconductor layer from the first side, the method may include forming a plurality of first conductive connection lines in the semiconductor layer from the first side. In some implementations, the plurality of first conductive connection lines may be arranged along the second direction. In some implementations, the first conductive connection lines may extend along the third direction. In some implementations the first conductive connection lines may be connected to a plurality of first conductive connection structures arranged along the third direction. In some implementations, the forming the first conductive connection structure in the semiconductor layer from the first side may include forming the first conductive connection structure on the first conductive connection line in the semiconductor layer from the first side.

In some implementations, the forming the word line, the bit line, the first conductive connection structure and the second conductive connection structure may include providing a semiconductor layer including a first side and a second side opposite to each other along a thickness direction of the semiconductor layer. In some implementations, the forming the word line, the bit line, the first conductive connection structure and the second conductive connection structure may include forming the bit line and the word line on the semiconductor layer from the first side. In some implementations, the forming the word line, the bit line, the first conductive connection structure and the second conductive connection structure may include forming the second conductive connection structure on the bit line from the first side. In some implementations, the forming the word line, the bit line, the first conductive connection structure and the second conductive connection structure may include thinning the semiconductor layer from the second side. In some implementations, the forming the word line, the bit line, the first conductive connection structure and the second conductive connection structure may include forming the first conductive connection structure on the word line from the second side.

In some implementations, the method may include forming a plurality of first conductive connection lines on the first conductive connection structure from the second side. In some implementations, the plurality of first conductive connection lines may be arranged along the second direction, the first conductive connection lines extend along the third direction. In some implementations, the first conductive connection lines may be connected to a plurality of first conductive connection structures arranged along the third direction.

In some implementations, the method may include forming a first bonding layer from the first side. In some implementations, the first bonding layer may include a first bonding structure. In some implementations, the second conductive connecting structure may be located between the bit line and the first bonding layer. In some implementations, the first bonding structure may be coupled to the word line and the bit line.

In some implementations, the method may include forming a third conductive connection structure. In some implementations, two ends of the third conductive connection structure may be respectively connected to the first conductive connection line and the first bonding structure.

In some implementations, the method may include forming a pad structure on the first conductive connection line from the second side. In some implementations, the method may include forming a first interconnection structure. In some implementations, the pad structure and the first bonding structure may be connected through the first interconnection structure.

In the technical solution provided by the present disclosure, an end of the first conductive connection structure is connected to the word line, an end of the second conductive connection structure is connected to the bit line, the first conductive connection structure is located between the first surface and the word line, and the second conductive connection structure is located between the second surface and the bit line. That is, in the examples of the present disclosure, the word line and the bit line are led out from opposite directions, so that the difficulty of wiring can be reduced, and the area of wiring can be saved.

### BRIEF DESCRIPTION OF DRAWINGS

FIG. 1 is a schematic diagram of an electronic device provided by an example of the present disclosure;

FIG. 2 is a schematic diagram of a semiconductor device provided by an example of the present disclosure;

FIG. 3 is a schematic diagram of the three-dimensional structure of a semiconductor device provided by an example of the present disclosure;

FIG. 4a is a first cross-sectional view of a semiconductor device along an XZ plane provided by an example of the present disclosure;

FIG. 4b is a cross-sectional view of FIG. 4a along AA′ direction;

FIG. 4c is a first schematic diagram of a partial three-dimensional structure of a semiconductor device provided by an example of the present disclosure;

FIG. 5 is a second schematic diagram of a partial three-dimensional structure of a semiconductor device provided by an example of the present disclosure;

FIG. 6 is a second cross-sectional view of a semiconductor device along an XZ plane provided by an example of the present disclosure;

FIG. 7 is a schematic diagram of a distribution structure of a memory cell group provided by an example of the present disclosure;

FIG. 8 is a schematic diagram of a distribution structure of a memory cell subgroup provided by an example of the present disclosure;

FIG. 9 is a first schematic diagram of a structure of a memory device provided by an example of the present disclosure;

FIG. 10 is a second schematic diagram of a structure of a memory device provided by an example of the present disclosure;

FIG. 11 is a schematic flowchart of a method of manufacturing a semiconductor device provided by an example of the present disclosure;

FIGS. 12 to 18 are schematic diagrams of structures of a method of manufacturing a semiconductor device provided by an example of the present disclosure; and

FIGS. 19 to 25 are schematic diagrams of structures of a method of manufacturing a semiconductor device provided by another example of the present disclosure.

### DETAILED DESCRIPTION

Exemplary implementations disclosed in the present disclosure will be described in more detail below with reference to the accompanying drawings. Although exemplary implementations of the present disclosure are shown in the accompanying drawings, it is to be understood that the present disclosure may be implemented in various forms and should not be limited by the specific examples set forth herein. Rather, these examples are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; that is, not all features of the actual example are described herein, and well-known functions and structures are not described in detail.

In the drawings, like reference numbers refer to like elements throughout.

Herein, it should be understood that spatial relation terms such as “beneath,” “below,” “lower,” “under”, “above,” “upper,” etc., may be for ease of description to describe the relationship between one element or feature and other elements or features shown in the figures. It should be appreciated that in addition to the orientations shown in the figures, the spatial relation term is intended to also comprise different orientations of the devices in use and operation. For example, if the devices in the figures are flipped, then other elements or features described as “below” or “under” or “beneath” will be oriented “on” other elements or features. Thus, the exemplary terms “below” and “under” may comprise both upper and lower orientations. The devices may be additionally oriented (rotated 90 degrees or other orientations) and the spatial description terminology used herein is interpreted accordingly.

A term used herein is for the purpose of describing a particular example only and is not to be considered as limitation of the present disclosure. As used herein, the singular forms “a”, “an” and “said/the” are intended to comprise the plural forms as well, unless the context clearly dictates otherwise. It should also be understood that the terms “consists of” and/or “comprising”, when used in this description, identify the presence of stated features, integers, steps, operations, elements and/or parts, but do not exclude the presence or addition of one or more other features, integers, steps, operations, elements, parts and/or groups. As used herein, the term “and/or” comprises any and all combinations of the associated listed items.

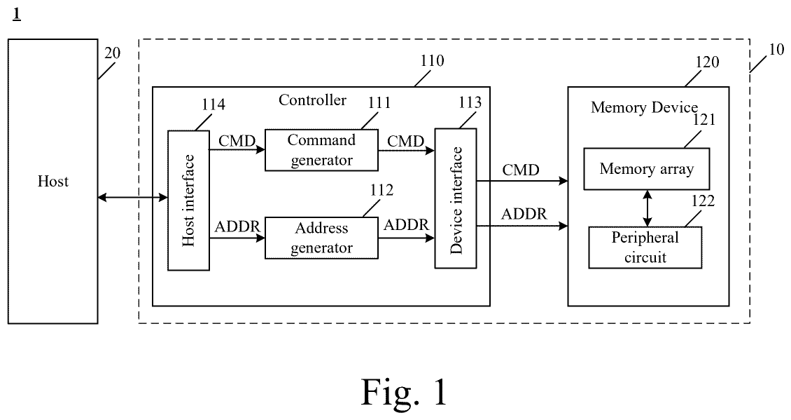

FIG. 1 is a schematic diagram of an electronic device 1 provided by an example of the present disclosure. The electronic device 1 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory device therein.

As shown in FIG. 1, the electronic device 1 may include a memory system 10 and a host 20, and the memory system 10 may include a controller 110 and a memory device 120. The host 20 may include a processor of the electronic device 1, for example, a central processing unit (CPU) or a system on chip (SoC) (for example, an application processor (AP)). The controller 110 is coupled to both the host 20 and the memory device 120, and the controller 110 may be configured to communicate with the host 20 and control the memory device 120.

In some examples, the controller 110 may be configured to control operations of the memory device 120, such as read operations, erase operations, write operations, refresh operations, and the like. In some implementations, the controller 110 is further configured to process Error Correction Code (ECC) regarding data read from or written to the memory device 120. In other implementations, the controller 110 may be further configured to perform any other suitable operations, such as formatting the memory device 120.

In some examples, the controller 110 may receive data, commands, and addresses from the host 20 and may send data, commands, and addresses to the memory device 120. In an example, the controller 110 may include a command generator 111, an address generator 112, a device interface 113, and a host interface 114. The controller 110 may receive data, commands, and addresses from the host 20 through the host interface 114, decode commands received from the host 20 by the command generator 111 to generate an access command CMD, and may provide the access command CMD to the memory device 120 through the device interface 113. The controller 110 may decode, by the address generator 112, the address received from the host interface 114 to generate an address ADDR to be accessed in the memory array 121, and may provide the address ADDR to be accessed to the memory device 120 through the device interface 113. The access command may be a signal instructing the memory device 120 to write or read data by accessing one or more memory cells in the memory array 121 corresponding to the address ADDR. In addition, the controller 110 may further send a refresh command to the memory device 120, and the refresh command may be a signal instructing the memory device 120 to read and re-write data by accessing one or more memory cells in the memory array 121 corresponding to the address ADDR.

In some examples, the memory device 120 may be a random access memory (RAM), for example, a dynamic random access memory, a synchronous dynamic random access memory (SDRAM), a static random access memory (SRAM), a double rate SDRAM (DDR SDRAM), a phase-change random access memory (PRAM), a resistive random access memory (ReRAM), a magnetic random access memory (MRAM), or the like. An example is described below in which the memory device 120 is a DRAM.

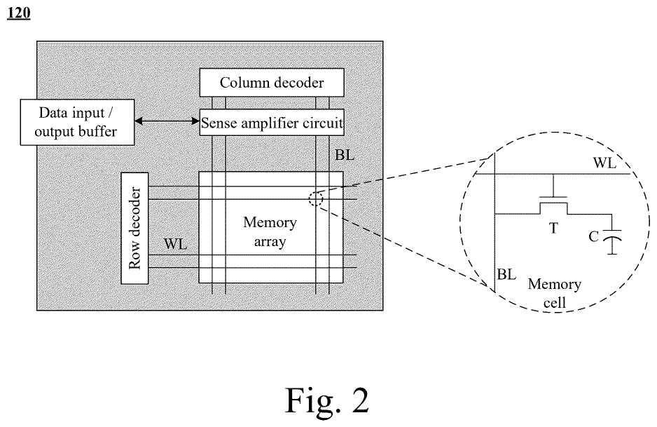

In some examples, FIG. 2 is a schematic diagram of a semiconductor device according to an example of the present disclosure. Referring to FIGS. 1 and 2, the semiconductor device includes a memory array 121 and a peripheral circuit 122 coupled to the memory array 121, the peripheral circuit 122 may include a sense amplifier circuit, a row decoder, a column decoder, a data input/output buffer, or the like, the memory array 121 includes a plurality of memory cells arranged in an array, a plurality of memory cells in a same row are coupled to the word line WL, and a plurality of memory cells in a same column are coupled to the bit line BL. Each memory cell includes a transistor T and a capacitor C, the word line WL is connected to the gate of the transistor T, the bit line BL is connected to one of the source and the drain of the transistor T, the other of the source and the drain of the transistor T is connected to one electrode of the capacitor C, and the other electrode of the capacitor C is connected to a fixed voltage. The memory cell is configured to store 1 or 0 with the amount of the charges stored in the capacitor C. By specifying the row address and the column address, each memory cell in the DRAM chip can be independently accessed, and the data stored in the memory cell can be read, written, or refreshed.

With the development of DRAM technology, the size of the memory cell is smaller and smaller, and the array architecture of the memory cell is from 8F² to 6F², and then to 4F² ; in addition, based on the demand for ion and leakage current in the DRAM, the architecture of the memory device has changed from a planar array transistor to a recess gate array transistor, from the recess gate array transistor to the buried saddle fin array transistor, and then from the buried saddle fin array transistor to the vertical gate transistor.

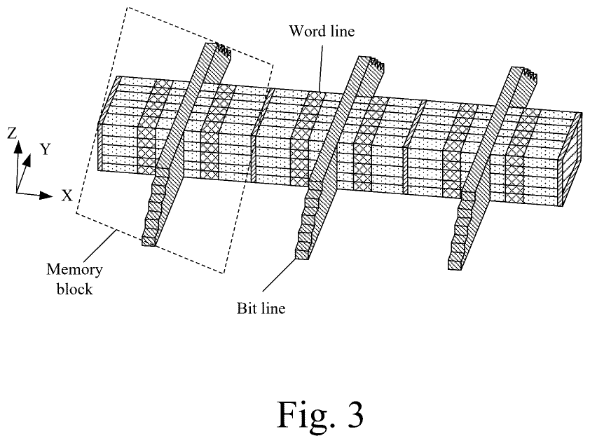

FIG. 3 is a schematic diagram of the three-dimensional structure of a semiconductor device according to an example of the present disclosure. In some examples, as shown in FIG. 3, the word line extends along the Z-axis direction, the bit line extends along the Y-axis direction, and the semiconductor body of the vertical gate transistor extends along the X-axis direction. In such architecture, the size of the single memory block along the X-axis direction is small, so that the sense amplifier circuit and the word line driver circuit corresponding to the memory block cannot be placed below the memory array. In some examples, the word lines of the plurality of memory blocks may be connected in parallel by a conductive line extending along the X-axis direction, so that the word lines of the plurality of memory blocks may operate simultaneously. How to reasonably set the conductive line becomes an urgent problem to be solved.

To overcome these and other challenges, the present disclosure provides the following implementations.

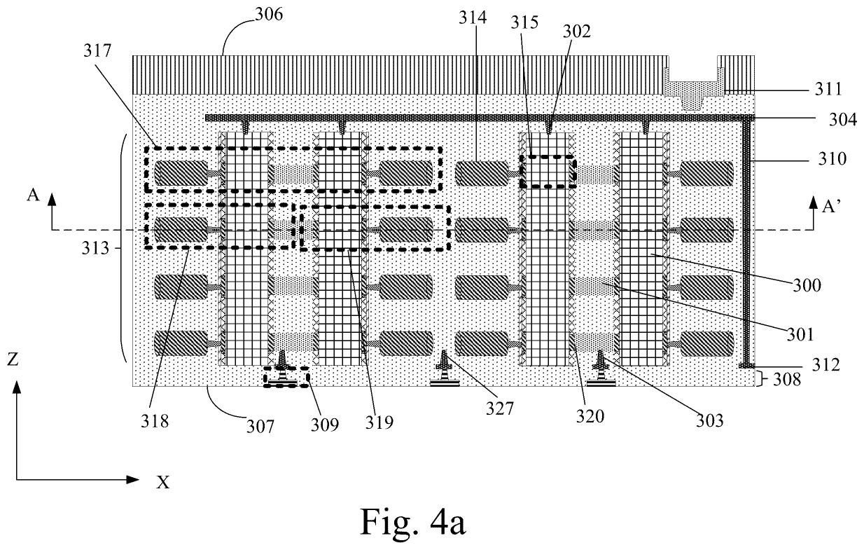

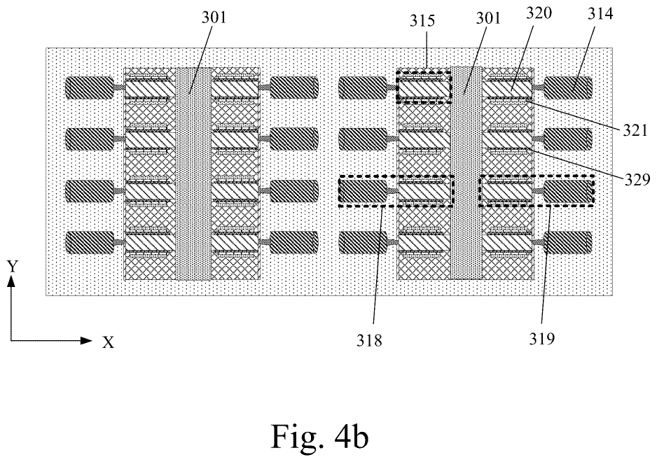

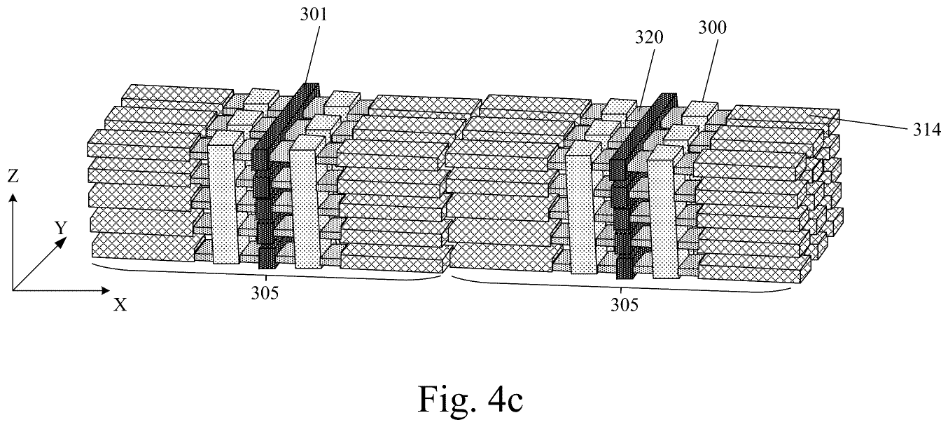

An example of the present disclosure provides a semiconductor device, as shown in FIGS. 4a, 4b and 4c. The semiconductor device includes a word line 300 extending along a first direction; a bit line 301 extending along a second direction, where the second direction intersects with the first direction. The semiconductor device includes a first conductive connection structure 302 located between the first surface 306 and the word line 300, where an end of the first conductive connection structure 302 is connected to the word line 300, and the first surface 306 and the second surface 307 are two opposite surfaces of the semiconductor device along the first direction. The semiconductor device includes a second conductive connection structure 303 located between the second surface 307 and the bit line 301, where an end of the second conductive connection structure 303 is connected to the bit line 301.

FIG. 4a is a first cross-sectional view of a semiconductor device along an XZ plane provided by an example of the present disclosure; FIG. 4b is a cross-sectional view of FIG. 4a along AA′ direction; and FIG. 4c is a schematic diagram of a partial three-dimensional structure of a semiconductor device provided by an example of the present disclosure.

In the examples of the present disclosure, an end of the first conductive connection structure 302 is connected to the word line 300, an end of the second conductive connection structure 303 is connected to the bit line 301, the first conductive connection structure 302 is located between the first surface 306 and the word line 300, and the second conductive connection structure 303 is located between the second surface 307 and the bit line 301. That is, in the examples of the present disclosure, the word line 300 and the bit line 301 are led out from opposite directions, so that the difficulty of wiring can be reduced, and the area of wiring can be limited.

The first direction here intersects with the second direction, and the third direction mentioned later intersects with both the first direction and the second direction. In the examples of the present disclosure, the example is taken as an example for illustration where the first direction is perpendicular to the second direction and the third direction is perpendicular to both the second direction and the first direction, but the present disclosure is not limited thereto. The first direction in is the Z-axis direction in the drawings of the present disclosure, the second direction is the Y-axis direction in the drawings of the present disclosure, and the third direction is the X-axis direction in the drawings of the present disclosure.

In the examples of the present disclosure, as shown in FIG. 4a, the first conductive connection structure 302 extends along a first direction, and one of two opposite ends of the first conductive connection structure 302 along the first direction is connected to the word line 300. The second conductive connection structure 303 extends along a first direction, and one of two opposite ends of the second conductive connection structure 303 to each other is connected to the bit line 301.

The materials of the first conductive connection structure 302, the second conductive connection structure 303, the word line 300, and the bit line 301 are each a conductive material, and the conductive material herein may be one of a doped semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

In some examples, as shown in FIGS. 4a, 4b, and 4c, the semiconductor device includes a plurality of word lines 300 and a plurality of first conductive connection structures 302, where the plurality of word lines 300 are arranged in an array along the second direction and the third direction, the plurality of word lines 300 are connected to the plurality of first conductive connection structures 302 in a one-to-one correspondence, and the third direction intersects with the second direction and the first direction.

In the examples of the present disclosure, the plurality of word lines 300 are arranged in an array along the second direction and the third direction, the plurality of word lines 300 are connected to the plurality of first conductive connection structures 302 in a one-to-one correspondence, and the plurality of the first conductive connection structures 302 are arranged in an array along the second direction and the third direction.

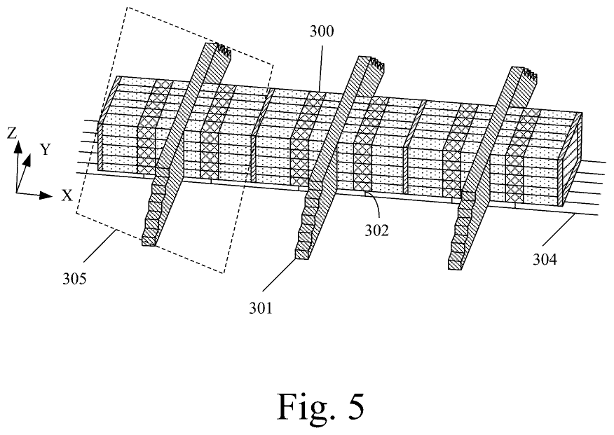

In some examples, as shown in FIGS. 4a and 5, the semiconductor device further includes a plurality of first conductive connection lines 304, where the plurality of first conductive connection lines 304 are arranged along the second direction, the first conductive connection lines 304 extend along the third direction, and the first conductive connection lines 304 are connected to the plurality of first conductive connection structures 302 arranged along the third direction.

The material of the first conductive connection line 304 is a conductive material, and the conductive material herein may be one of a doped semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

In the examples of the present disclosure, the first conductive connection lines 304 are connected to the plurality of first conductive connection structures 302 arranged along the third direction, so that the plurality of word lines 300 arranged along the third direction may operate simultaneously.

In some examples, as shown in FIGS. 4c and 5, the semiconductor device includes a plurality of memory blocks 305 arranged along the third direction, where the first conductive connection lines 304 are connected to the plurality of first conductive connection structures 302 arranged along the third direction in the plurality of memory blocks 305.

In the examples of the present disclosure, each of the plurality of memory blocks 305 of the semiconductor device includes a plurality of word lines 300 and a plurality of first conductive connection structures 302, the plurality of word lines 300 in the memory block 305 are arranged in an array along the second direction and the third direction, and the plurality of word lines 300 included in the plurality of memory blocks 305 as a whole are arranged in an array along the second direction and the third direction. As shown in FIG. 5, the first conductive connection lines 304 are connected to the plurality of first conductive connection structures 302 arranged along the third direction of the plurality of memory blocks 305 arranged along the third direction, so that the first conductive connection lines 304 are connected to the word lines 300 of the plurality of memory blocks 305 arranged along the third direction, so that the plurality of word lines 300 arranged along the third direction of the plurality of memory blocks 305 arranged along the third direction can operate simultaneously.

It should be noted that the number of the memory blocks 305 in the semiconductor device described in FIGS. 4c and 5 is merely an example, and is not intended to limit the number of the memory blocks 305 in the examples of the present disclosure.

In some examples, the second conductive connection structure 303 is located on the stairs shown in FIG. 5.

In some examples, as shown in FIG. 4a, the first conductive connection line 304 is located between the first conductive connection structure 302 and the first surface 306.

In the examples of the present disclosure, the first conductive connection structure 302 is located between the first surface 306 and the word line 300, the second conductive connection structure 303 is located between the second surface 307 and the bit line 301, and the word line 300 and the bit line 301 are led out in opposite directions, so that the first conductive connection line 304 connected to the plurality of first conductive connection structures 302 arranged along the third direction may be disposed between the first surface 306 and the first conductive connection structure 302, thereby reducing the difficulty of wiring and saving the area of wiring.

In some examples, as shown in FIG. 4a, along a direction perpendicular to the first direction, a size of an end of two opposite ends of the first conductive connection structure 302 closer to the word line 300 along the first direction is a first size; along the direction perpendicular to the first direction, a size of an end of two opposite ends of the first conductive connection structure 302 farther from the word line 300 along the first direction is a second size; and the first size is greater than the second size.

The direction perpendicular to the first direction herein includes a third direction and a second direction.

In the above example, as shown in FIG. 4a, a size of the first conductive connection structure 302 along the third direction gradually increases in a direction pointing from the second surface 307 to the first surface 306.

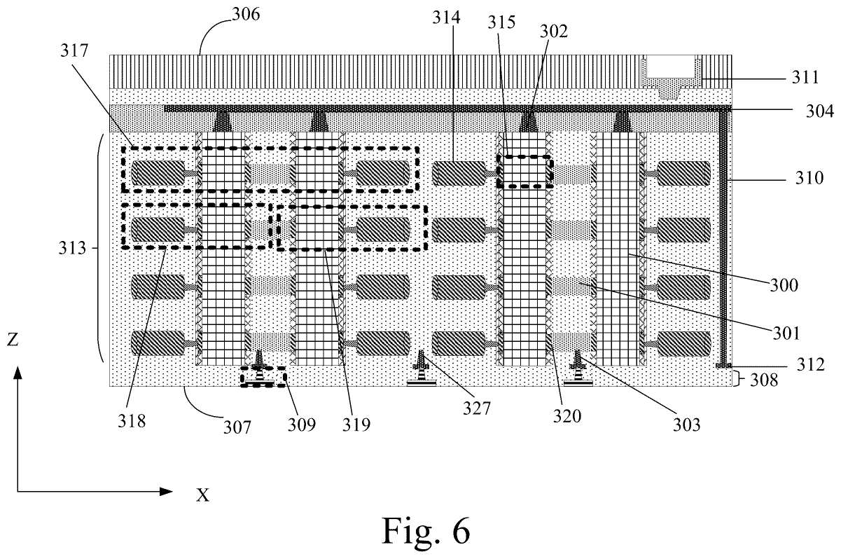

In some examples, as shown in FIG. 6, along a direction perpendicular to the first direction, a size of an end of two opposite ends of the first conductive connection structure 302 closer to the word line 300 along the first direction is a first size; along the direction perpendicular to the first direction, a size of an end of two opposite ends of the first conductive connection structure 302 farther from the word line 300 along the first direction is a second size; and the first size is greater than the second size.

In the above example, as shown in FIG. 6, a size of the first conductive connection structure 302 along the third direction gradually decreases in a direction pointing from the second surface 307 to the first surface 306.

In some examples, as shown in FIGS. 4a and 6, the semiconductor device further includes a first bonding layer 308, and the first bonding layer 308 includes a first bonding structure 309; the first bonding layer 308 is located on the side that is among two opposite sides of the word line 300 along the first direction and close to the second surface 307; and the first bonding structure 309 is coupled to the word line 300 and the bit line 301.

In some examples, the first bonding layer 308 is a hybrid bonding layer, and the material of the first bonding structure 309 includes a metal material, including, but is not limited to, aluminum, copper, tungsten, titanium, and tantalum.

In some examples, as shown in FIGS. 4a and 6, the semiconductor device further includes a third conductive connection structure 310.

In some examples, the third conductive connection structure 310 extends along the first direction, and two opposite ends of the third conductive connection structure 310 along the first direction are respectively connected to the first conductive connection line 304 and the first bonding structure 309. In some other examples, as shown in FIGS. 4a and 6, two opposite ends of the third conductive connection structure 310 along the first direction are respectively connected to the first conductive connection line 304 and the second interconnection structure 312, and the second interconnection structure 312 is connected to the first bonding structure 309.

In some examples, as shown in FIGS. 4a and 6, the semiconductor device further includes a pad structure 311 and a first interconnection structure, where the pad structure 311 is located on the side of the first conductive connection line 304 that is close to the first surface 306, and the pad structure 311 and the first bonding structure 309 are connected through the first interconnection structure.

In some examples, the materials of the pad structure 311, the first interconnect structure, the second interconnect structure, and the third conductive connection structure 310 each include a conductive material, where the conductive material may be one of a doped semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

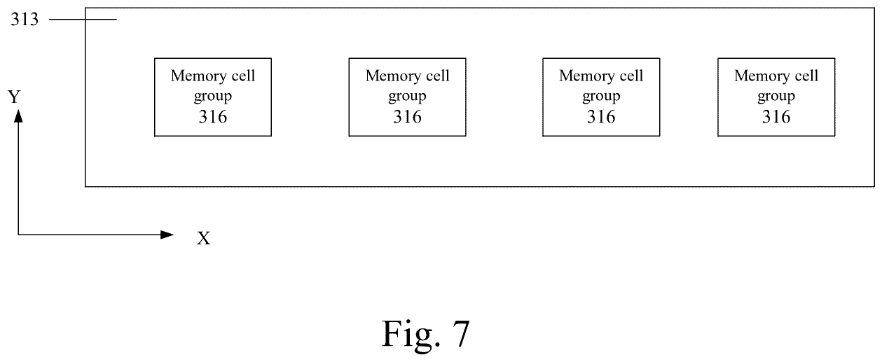

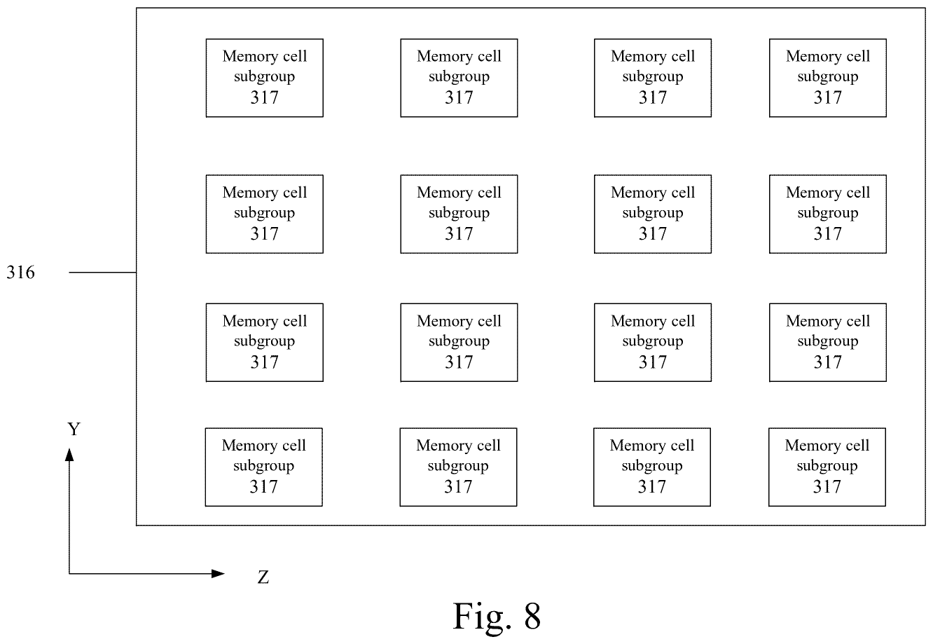

In some examples, as shown in FIGS. 4a and 6, the semiconductor device includes a memory layer 313 including a plurality of word lines 300, a plurality of bit lines 301, and a plurality of memory cells; the memory cell includes a capacitor structure 314 and a transistor structure 315 arranged along the third direction. As shown in FIG. 7, the plurality of memory cells constitute a plurality of memory cell groups 316 arranged along the third direction. As shown in FIG. 8, the memory cell group 316 includes a plurality of memory cell subgroups 317 arranged in an array along the first direction and the second direction. As shown in FIGS. 4a and 6, the memory cell subgroup 317 includes a first memory cell 318 and a second memory cell 319 arranged along the third direction. One of the word lines 300 is connected to the first memory cell 318 or the second memory cell 319 of the plurality of memory cell subgroups 317 arranged along the first direction, and one of the bit lines 301 is connected to a first memory cell 318 and a second memory cell 319 of the plurality of memory cell subgroups 317 arranged along the second direction.

In the examples of the present disclosure, each memory block 305 includes a plurality of memory cells, and a plurality of memory cells in the memory block 305 constitute a memory cell group 316. Each memory cell group 316 includes a plurality of memory cell subgroups 317 arranged in an array along the first direction and the second direction. The memory cell subgroup 317 includes a first memory cell 318 and a second memory cell 319 arranged along the third direction. The first memory cell 318 and the second memory cell 319 in the memory cell subgroup 317 share the same bit line 301. The plurality of memory cell subgroups 317 arranged along the second direction share the same bit line 301. A plurality of first memory cells 318 in the plurality of memory cell subgroups 317 arranged along the first direction are arranged along the first direction, and the plurality of first memory cells 318 of the plurality of memory cell subgroups 317 arranged along the first direction share one word line 300. A plurality of second memory cells 319 in the plurality of memory cell subgroups 317 arranged along the first direction are arranged along the first direction, and the plurality of second memory cells 319 of the plurality of memory cell subgroups 317 arranged along the first direction share one word line 300.

In the examples of the present disclosure, as shown in FIG. 4b, the transistor structure 315 is a vertical transistor including a semiconductor body 320 extending along the third direction, and the first memory cell 318 and the second memory cell 319 in the memory cell subgroup 317 share the bit line 301, which facilitates the reduction of the area of the semiconductor device and the improvement of the memory density.

In some examples, as shown in FIG. 4b, the transistor structure 315 includes a semiconductor body 320, where the semiconductor body 320 extends along the third direction, and two opposite ends of the semiconductor body 320 along the third direction are respectively connected to the bit line 301 and the capacitor structure 314. The transistor structure 315 includes a gate structure 321, where the gate structure 321 surrounds the semiconductor body 320, and a plurality of gate structures 321 arranged along the first direction are connected to each other to form the word line 300.

In some examples, the semiconductor body 320 includes a first electrode structure, a channel structure, and a second electrode structure that are sequentially arranged along the third direction, the first electrode structure herein may be one of the source or the drain of the transistor structure 315, and the second electrode structure may be the other one of the source or the drain of the transistor structure 315. The gate structure 321 is located on two opposite sides of the channel structure along the first direction and two opposite sides of the channel structure along the second direction. That is, the gate structure 321 surrounds the channel structure to form a gate-all-around vertical transistor.

In some examples, the material of the semiconductor body 320 includes, but is not limited to, an elemental semiconductor material (e.g., silicon (Si) or germanium (Ge), etc. ), a III-V compound semiconductor material (e.g., gallium nitride (GaN), gallium arsenide (GaAs), or indium phosphide (InP), etc. ), a II-VI compound semiconductor material (e.g., zinc sulfide (ZnS), cadmium sulfide (CdS), or cadmium telluride (CdTe), etc. ), an organic semiconductor material, or other semiconductor material known in the art. The material of the gate structure 321 includes a conductive material, such as at least one of a doped semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

It should be noted that the arrangement of the gate structure 321 in FIGS. 4a and 4b is merely an example, and in other examples, the gate structure 321 is located on at least one side of the channel structure along a direction perpendicular to the third direction, and the gate structure 321 may be located on one side, two sides and three sides of the channel structure, which is not specifically limited in the present disclosure.

In some examples, as shown in FIG. 4b, the transistor structure 315 further includes a gate dielectric layer 329, and the gate dielectric layer 329 is located between the gate structure 321 and the channel structure of the semiconductor body 320. The gate dielectric layer 329 may include at least one of a high dielectric material, silicon oxide, silicon nitride, and silicon oxynitride, where the high dielectric material may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In some examples, the capacitor structure 314 includes a first electrode plate, a second electrode plate, and a dielectric layer between the first electrode plate and the second electrode plate. In other examples, the capacitor structure 314 may have any other suitable structure, which is not specifically limited in the present disclosure. One end of two opposite ends of the semiconductor body 320 along the third direction is connected to the first electrode plate of the capacitor structure 314, the second electrode plates of the plurality of capacitor structures 314 arranged along the first direction are connected, the second electrode plates of the adjacent capacitor structures 314 of the two adjacent memory cell subgroups 317 along the third direction are connected, and the second electrode plate of the capacitor structure 314 is connected to the fourth conductive connection structure 327 as shown in FIGS. 4a and 6.

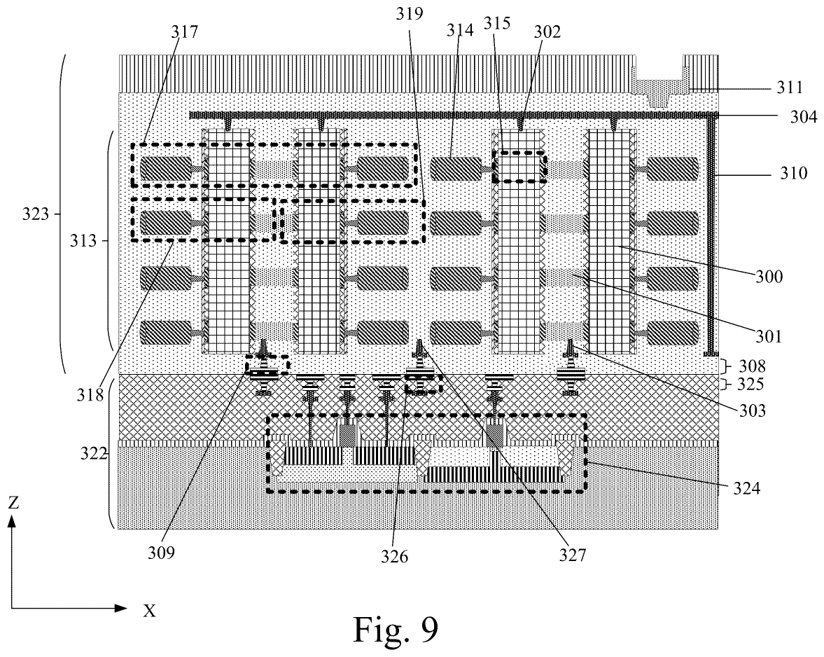

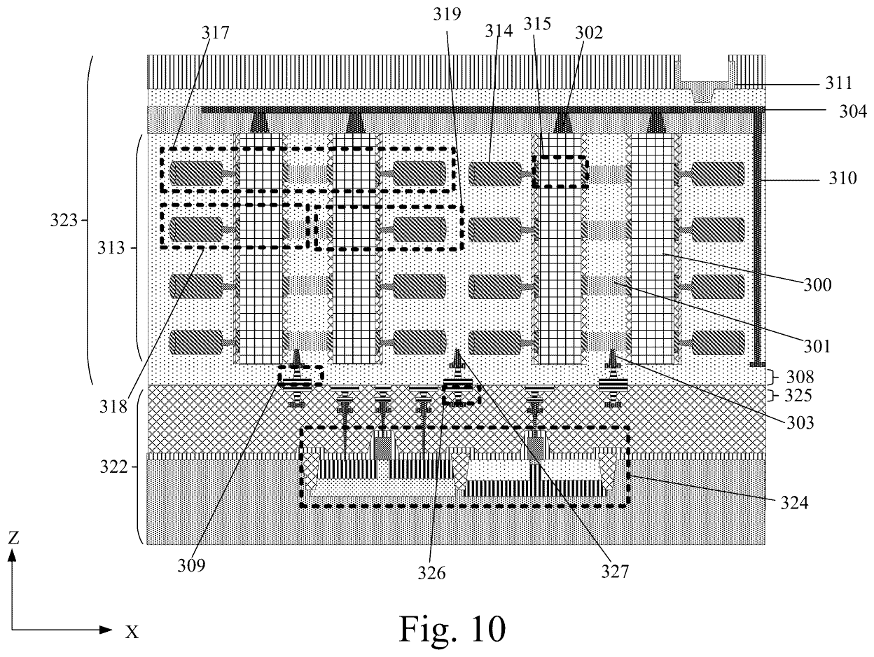

Based on a similar concept as the above semiconductor device, the present disclosure further provides a memory device, as shown in FIGS. 9 and 10, the memory device includes a first semiconductor structure 322 and a second semiconductor structure 323 stacked along a first direction, where the first semiconductor structure 322 includes a peripheral circuit 324. The second semiconductor structure 323 includes a word line 300. The word line 300 extends along the first direction. A bit line 301, where the bit line 301 extends along a second direction, and the second direction intersects with the first direction. A first conductive connection structure 302, where the first conductive connection structure 302 is located on a side of two opposite sides of the word line 300 along the first direction that is far from the first semiconductor structure 322. An end of the first conductive connection structure 302 is connected to the word line 300.

In the examples of the present disclosure, an end of the first conductive connection structure 302 is connected to the word line 300, and the first conductive connection structure 302 is located on one side of two opposite sides of the word line 300 along the first direction that is far from the first semiconductor structure 322, so that the pressure of wiring between the memory array and the peripheral circuit 324 may be reduced, the difficulty of wiring can be reduced, and the area of wiring can be limited.

In some examples, as shown in FIGS. 9 and 10, the second semiconductor structure 323 further includes a second conductive connection structure 303, where the second conductive connection structure 303 is located between the bit line 301 and the first semiconductor structure 322, and an end of the second conductive connection structure 303 is connected to the bit line 301.

In some examples, as shown in FIGS. 9 and 10, the first semiconductor structure 322 further includes a second bonding layer 325, the second bonding layer 325 includes a second bonding structure 326, and the second bonding layer 325 is located between the peripheral circuit 324 and the second semiconductor structure 323. The second semiconductor structure 323 further includes a first bonding layer 308, the first bonding layer 308 includes a first bonding structure 309, the first bonding layer 308 is located between the first semiconductor structure 322 and the word line 300 or the bit line 301. The second bonding structure 326 is coupled to the peripheral circuit 324, the first bonding structure 309 is coupled to the word line 300 and the bit line 301, and the first bonding structure 309 is connected to the second bonding structure 326.

In some examples, the first bonding layer 308 and the second bonding layer 325 may be hybrid bonding layers, and both the first bonding structure 309 and the second bonding structure 326 may be metal-metal bonding structures.

In the examples of the present disclosure, the first semiconductor structure 322 and the second semiconductor structure 323 are stacked along the first direction, so that the memory array and the peripheral circuit 324 can be arranged along the stacking direction of the memory device. On one hand, the length of the connection line between the memory array and the peripheral circuit 324 can be reduced, and the reliability of signal transmission can be improved; on the other hand, the area occupied by the memory array can be reduced, which facilitates the miniaturization development of the memory device.

In some examples, the second semiconductor structure 323 includes a plurality of word lines 300 and a plurality of first conductive connection structures 302. The plurality of word lines 300 are arranged in an array along the second direction and the third direction. The plurality of word lines 300 are connected to the plurality of first conductive connection structures 302 in a one-to-one correspondence. The third direction intersects with the second direction and the first direction.

In some examples, as shown in FIGS. 9 and 10, the second semiconductor structure 323 further includes a plurality of first conductive connection lines 304. The plurality of first conductive connection lines 304 are arranged along the second direction. The first conductive connection lines 304 extend along the third direction. The first conductive connection lines 304 are connected to the plurality of first conductive connection structures 302 arranged along the third direction.

In some examples, as shown in FIG. 5, the second semiconductor structure 323 includes a plurality of memory blocks 305 arranged along the third direction; and the first conductive connection lines 304 are connected to the plurality of first conductive connection structures 302 arranged along the third direction in the plurality of memory blocks 305.

In some examples, as shown in FIGS. 9 and 10, the first conductive connection line 304 and the first bonding layer 308 are respectively located on two opposite sides of the word line 300 along the first direction.

In some examples, as shown in FIG. 10, along a direction perpendicular to the first direction, a size of an end of two opposite ends of the first conductive connection structure 302 closer to the word line along the first direction is a first size. Along the direction perpendicular to the first direction, a size of an end of two opposite ends of the first conductive connection structure farther from the word line along the first direction is a second size. The first size is greater than the second size.

In some examples, as shown in FIG. 9, along a direction perpendicular to the first direction, a size of an end of two opposite ends of the first conductive connection structure 302 closer to the word line 300 along the first direction is a first size. Along the direction perpendicular to the first direction, a size of an end of two opposite ends of the first conductive connection structure 302 farther from the word line 300 along the first direction is a second size. The first size is smaller than the second size.

In some examples, as shown in FIGS. 9 and 10, the second semiconductor structure 323 further includes a third conductive connection structure 310. Two ends of the third conductive connection structure 310 are respectively connected to the first conductive connection line 304 and the first bonding structure 309.

In some examples, as shown in FIGS. 9 and 10, the second semiconductor structure 323 further includes a pad structure 311 and a first interconnection structure, where the first conductive connection line 304 is located between the pad structure 311 and the first conductive connection structure 302, and the pad structure 311 and the first bonding structure 309 are connected through the first interconnection structure.

In some examples, as shown in FIGS. 7 to 10, the second semiconductor structure 323 includes a memory layer 313, the memory layer 313 includes a plurality of word lines 300, a plurality of bit lines 301, and a plurality of memory cells. The memory cell includes a capacitor structure 314 and a transistor structure 315 arranged along the third direction. The plurality of memory cells constitute a plurality of memory cell groups 316 arranged along the third direction. The memory cell group 316 includes a plurality of memory cell subgroups 317 arranged in an array along the first direction and the second direction. The memory cell subgroup 317 includes a first memory cell 318 and a second memory cell 319 arranged along the third direction. One word line 300 is connected to the first memory cell 318 or the second memory cell 319 of the plurality of memory cell subgroups 317 arranged along the first direction. One bit line 301 is connected to the first memory cell 318 and the second memory cell 319 of the plurality of memory cell subgroups 317 arranged along the second direction.

In some examples, as shown in FIG. 4b, the transistor structure 315 includes a semiconductor body 320, where the semiconductor body 320 extends along the third direction, and two opposite ends of the semiconductor body 320 along the third direction are respectively connected to the bit line 301 and the capacitor structure 314. The transistor structure 315 includes a gate structure 321, where the gate structure 321 surrounds the semiconductor body 320, and a plurality of gate structures 321 arranged along the first direction are connected to each other to form the word line 300.

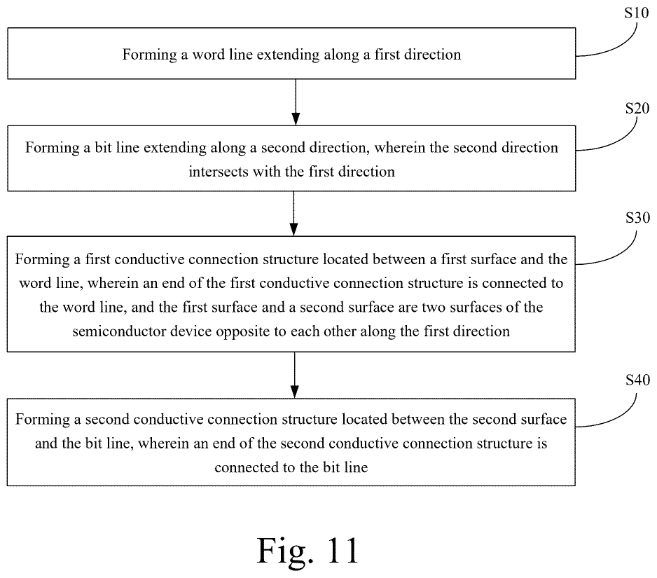

Based on a similar concept as the semiconductor device above, the present disclosure further provides a method of manufacturing a semiconductor device. FIG. 11 is a schematic flowchart of a method of manufacturing a semiconductor device provided by an example of the present disclosure.

Operation S10 may include forming a word line extending along a first direction;

Operation S20 may include forming a bit line extending along a second direction, where the second direction intersects with the first direction;

Operation S30 may include forming a first conductive connection structure located between a first surface and the word line, where an end of the first conductive connection structure is connected to the word line, and the first surface and a second surface are two surfaces of the semiconductor device opposite to each other along the first direction;

Operation S40 may include forming a second conductive connection structure located between the second surface and the bit line, where an end of the second conductive connection structure is connected to the bit line.

It should be understood that the operations shown in FIG. 11 are not exclusive, and other operations may be performed before, after, or between any operations in the illustrated operations; the operations shown in FIG. 11 may be sequentially adjusted as appropriate.

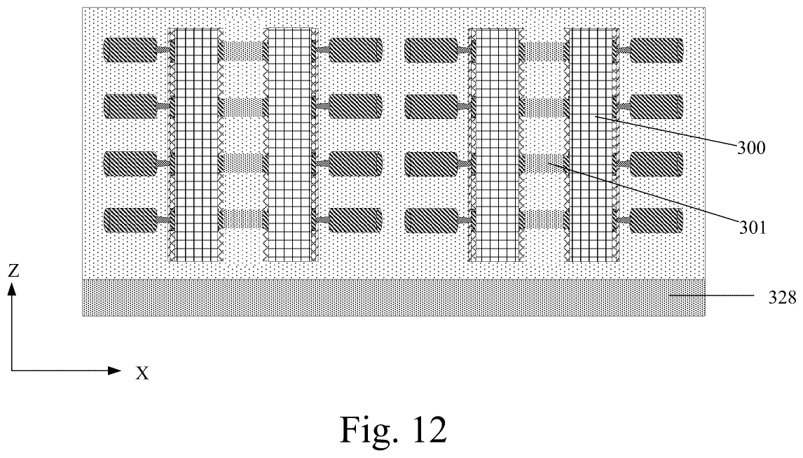

FIGS. 12 to 18 are schematic diagrams of structures of a method of manufacturing a semiconductor device provided by an example of the present disclosure. The manufacturing method of the semiconductor device provided by the examples of the present disclosure will be described below with reference to FIGS. 12 to 18.

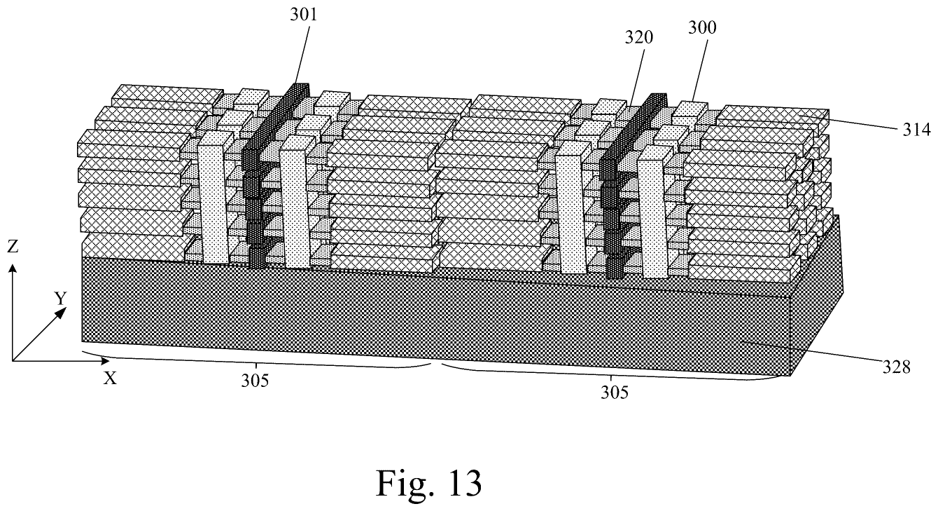

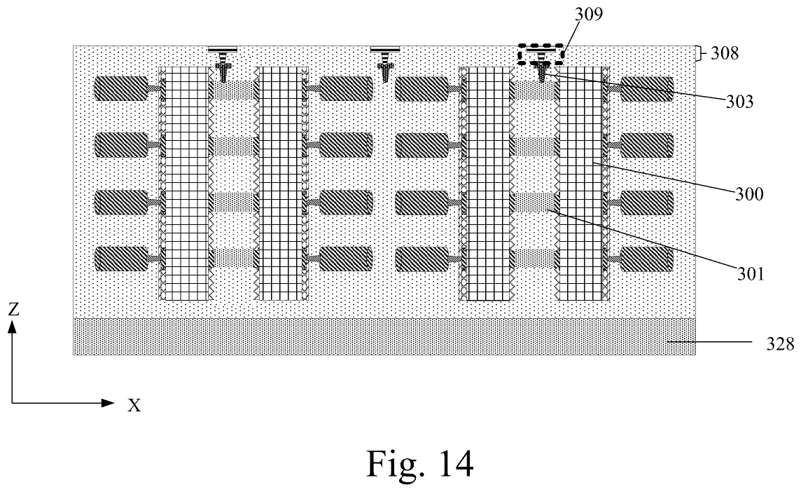

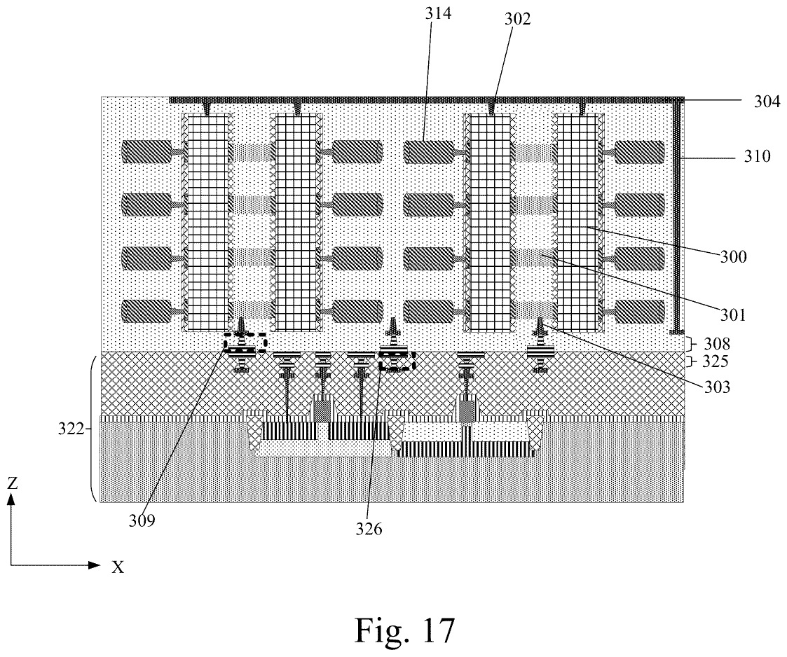

In some examples, forming the word line, the bit line, the first conductive connection structure and the second conductive connection structure includes providing a semiconductor layer 328 as shown in FIGS. 12 and 13, where the semiconductor layer 328 includes a first side and a second side opposite to each other along a thickness direction of the semiconductor layer 328. Forming the word line, the bit line, the first conductive connection structure and the second conductive connection structure includes forming the bit line 301 and the word line 300 on the semiconductor layer 328 from the first side. As shown in FIG. 14, forming the word line, the bit line, the first conductive connection structure and the second conductive connection structure includes forming the second conductive connection structure 303 on the bit line 301 from the first side. As shown in FIG. 17, forming the word line, the bit line, the first conductive connection structure and the second conductive connection structure includes thinning the semiconductor layer 328 from the second side. Forming the word line, the bit line, the first conductive connection structure and the second conductive connection structure includes forming the first conductive connection structure 302 on the word line 300 from the second side.

In some examples, the semiconductor layer 328 may be a substrate, and the material of the substrate may include at least one of silicon, germanium, silicon germanium and other semiconductor materials.

In some examples, the method further includes, as shown in FIG. 14, forming a first bonding layer 308 from the first side, where the first bonding layer 308 includes a first bonding structure 309. The second conductive connection structure is located between the bit line and the first bonding layer, and the first bonding structure is coupled to the word line and the bit line.

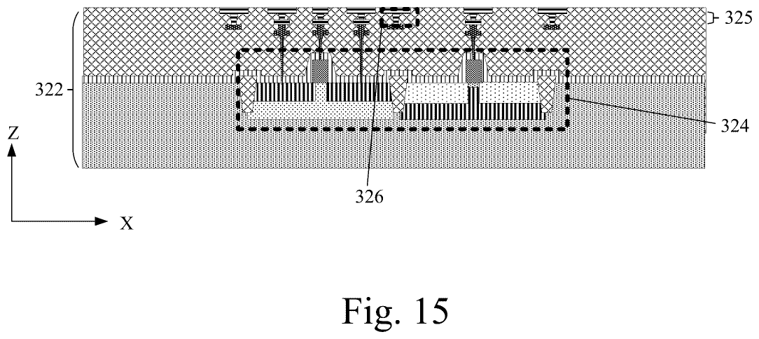

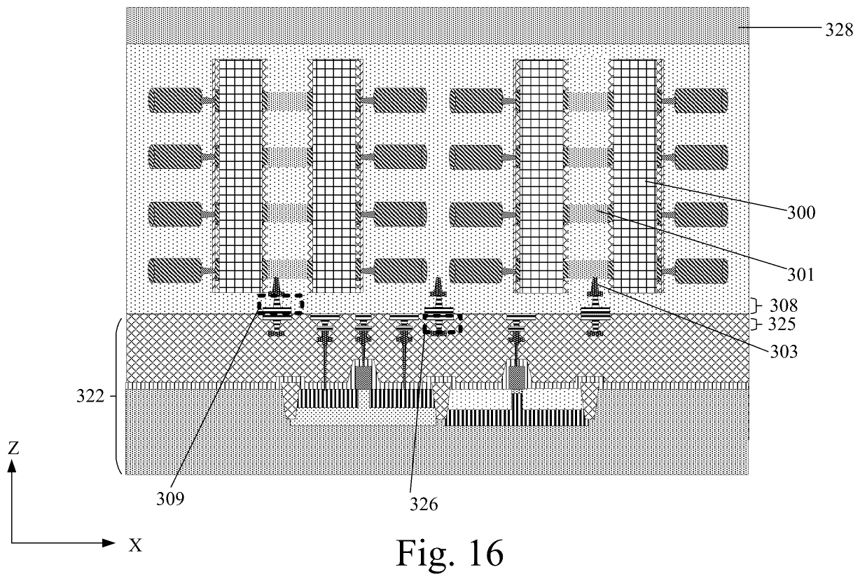

In some examples, as shown in FIG. 15, forming the memory device includes providing a first semiconductor structure 322 including a peripheral circuit 324 and a second bonding layer 325. As shown in FIG. 16, after the first bonding layer 308 is formed, the first bonding layer 308 and the second bonding layer 325 may be bonded, so that the first semiconductor structure 322 and the above semiconductor device are stacked along the first direction.

In some examples, as shown in FIG. 17, the method further includes forming a plurality of first conductive connection lines 304 on the first conductive connection structure 302 from the second side. Here, the plurality of first conductive connection lines 304 are arranged along the second direction, the first conductive connection lines 304 extend along the third direction, and the first conductive connection lines 304 are connected to the plurality of first conductive connection structures 302 arranged along the third direction.

In some examples, as shown in FIG. 17, the method further includes forming a third conductive connection structure 310, and two ends of the third conductive connection structure 310 are respectively connected to the first conductive connection line 304 and the first bonding structure 309.

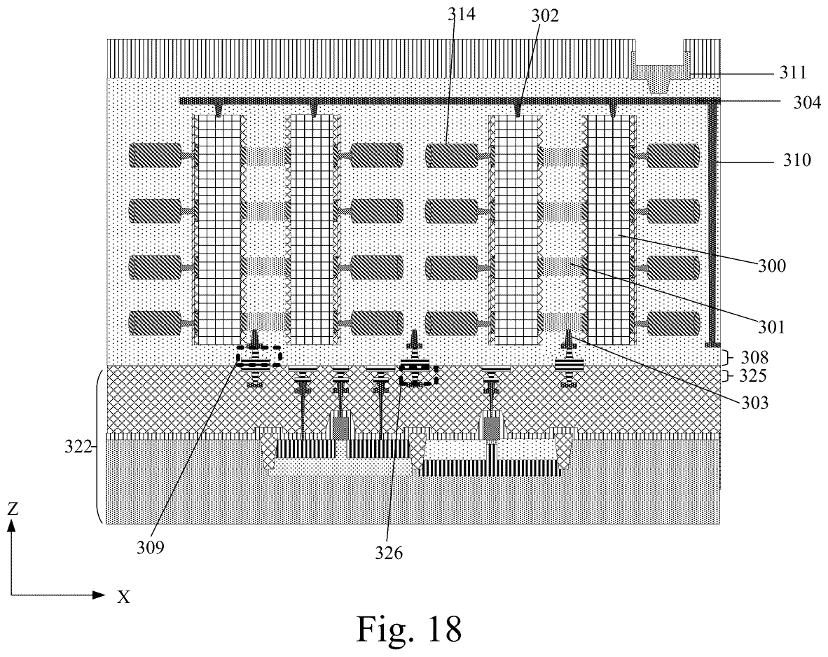

In some examples, as shown in FIG. 18, the method further includes forming a pad structure 311 on the first conductive connection line 304 from the second side; and the method further includes forming a first interconnection structure, where the pad structure 311 and the first bonding structure 309 are connected through the first interconnection structure.

In some examples, the bit line 301, the word line 300, the first conductive connection structure 302, the second conductive connection structure 303, the third conductive connection structure 310, the pad structure 311, the first interconnection structure, and the first conductive connection line 304 described above may be formed by an etching process and a deposition process. In the examples of the present disclosure, the deposition process includes, but is not limited to, chemical vapor deposition (CVD), low pressure chemical vapor deposition (LPCVD), plasma enhanced chemical vapor deposition (PECVD), physical vapor deposition (PVD), and atomic layer deposition (ALD). The etching process includes, but is not limited to, wet etching, plasma etching (PE), sputtering etching (SE), ion beam etching (IBE), and reactive ion etching (RIE).

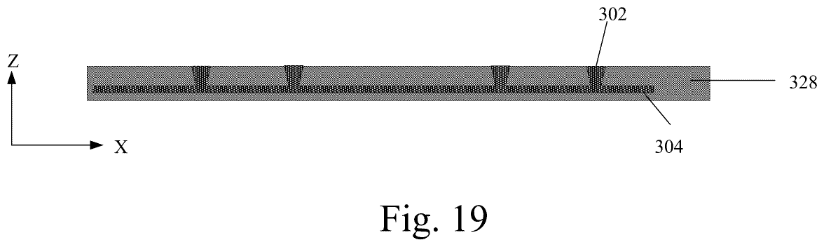

FIGS. 19 to 25 are schematic diagrams of structures of a method of manufacturing a semiconductor device provided by another example of the present disclosure. The manufacturing method of the semiconductor device provided by the examples of the present disclosure will be described below with reference to FIGS. 19 to 25.

In some examples, forming the word line, the bit line, the first conductive connection structure and the second conductive connection structure includes, as shown in FIG. 19, providing a semiconductor layer 328, where the semiconductor layer 328 includes a first side and a second side opposite to each other along a thickness direction of the semiconductor layer 328; and forming the word line, the bit line, the first conductive connection structure and the second conductive connection structure includes forming the first conductive connection structure 302 in the semiconductor layer 328 from the first side.

In some examples, the method further includes, as shown in FIG. 19, before forming the first conductive connection structure 302 in the semiconductor layer 328 from the first side, forming a plurality of first conductive connection lines 304 in the semiconductor layer 328 from the first side. Here, the plurality of first conductive connection lines 304 are arranged along the second direction, the first conductive connection lines 304 extend along the third direction, and the first conductive connection lines 304 are connected to a plurality of first conductive connection structures 302 arranged along the third direction. The forming the first conductive connection structure 302 in the semiconductor layer 328 from the first side includes forming the first conductive connection structure 302 on the first conductive connection lines 304 in the semiconductor layer 328 from the first side.

In the examples of the present disclosure, the first conductive connection structure 302 and the first conductive connection line 304 may be formed in the semiconductor layer 328 in a pre-buried manner.

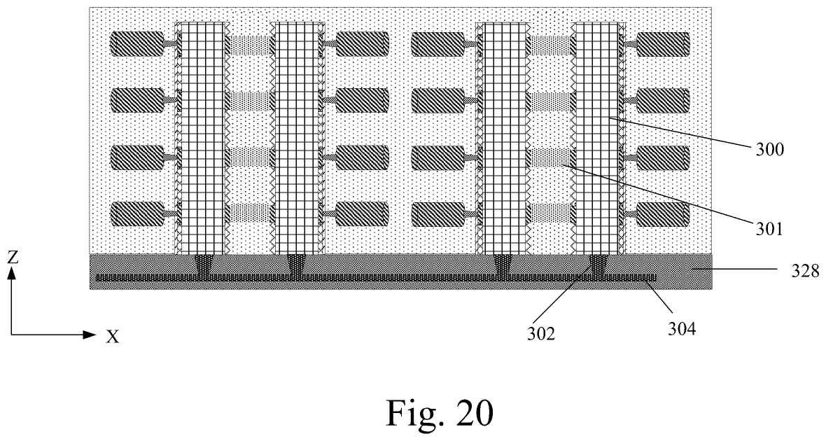

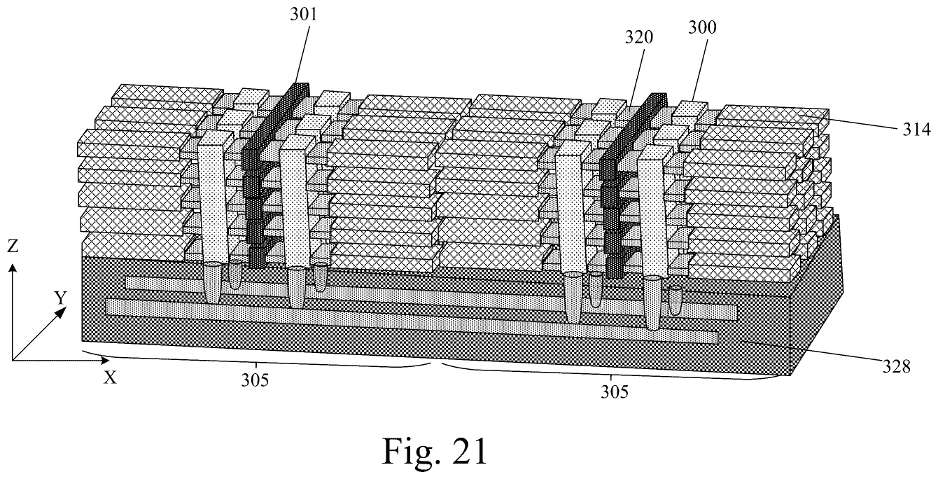

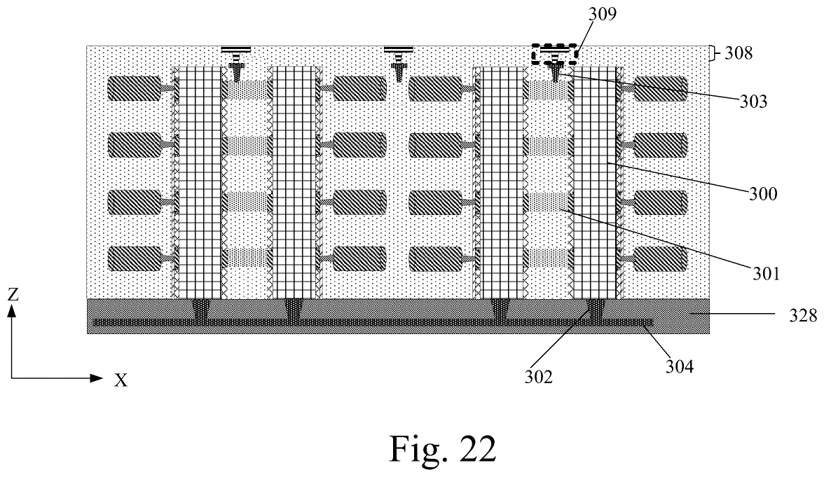

In some examples, forming the word line 300, the bit line 301, the first conductive connection structure 302 and the second conductive connection structure 303 includes: as shown in FIGS. 20 and 21, forming the bit line 301 and the word line 300 on the semiconductor layer 328 from the first side; and as shown in FIG. 22, forming the second conductive connection structure 303 on the bit line 301 from the first side.

In some examples, the method further includes, as shown in FIG. 22, forming a first bonding layer 308 from the first side, where the first bonding layer 308 includes a first bonding structure 309, the second conductive connecting structure is located between the bit line and the first bonding layer, and the first bonding structure is coupled to the word line and the bit line.

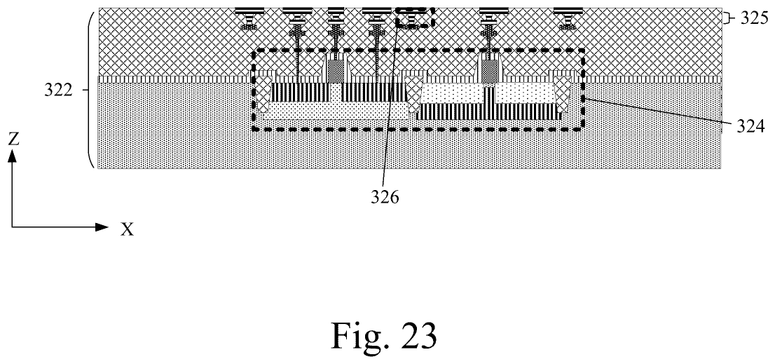

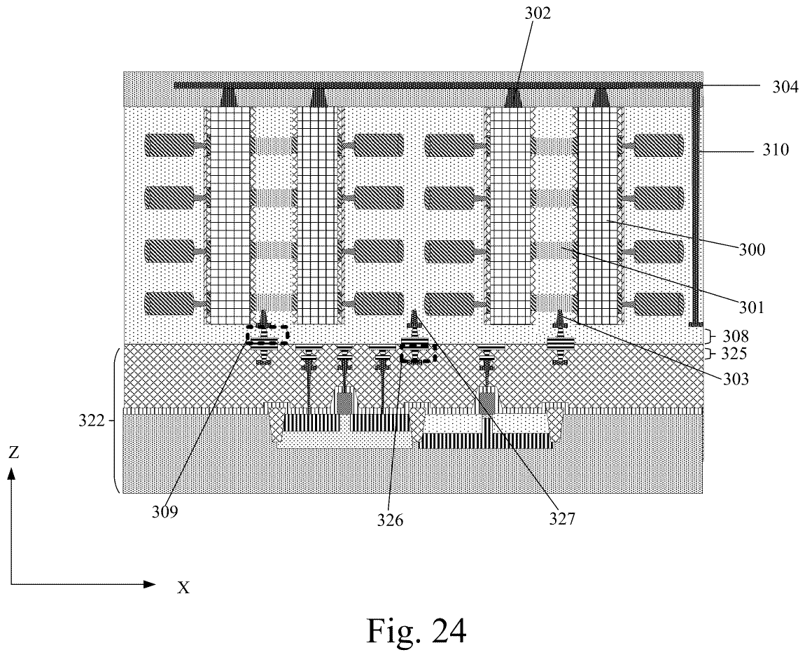

In some examples, as shown in FIG. 23, forming the memory device includes providing a first semiconductor structure 322 including a peripheral circuit 324 and a second bonding layer 325. As shown in FIG. 24, after the first bonding layer 308 is formed, the first bonding layer 308 and the second bonding layer 325 may be bonded, so that the first semiconductor structure 322 and the above semiconductor device are stacked along the first direction.

In some examples, as shown in FIG. 24, the method further includes forming a third conductive connection structure 310, where two ends of the third conductive connection structure 310 are respectively connected to the first conductive connection line 304 and the first bonding structure 309.

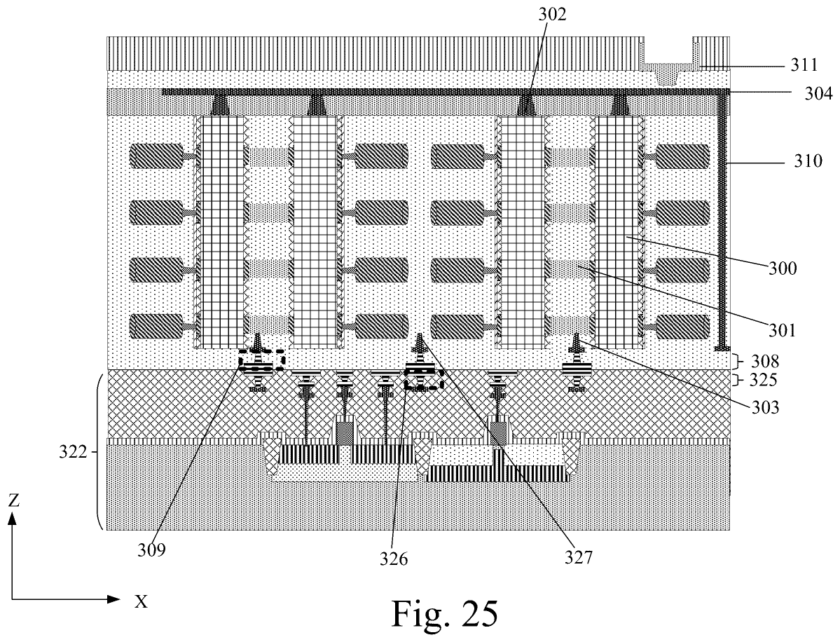

In some examples, as shown in FIG. 25, the method further includes: forming a pad structure 311 on the first conductive connection line 304 from the second side; forming a first interconnection structure, where the pad structure 311 and the first bonding structure 309 are connected through the first interconnection structure.

In some examples, the semiconductor device includes a plurality of word lines 300 and a plurality of first conductive connection structures 302, the plurality of word lines 300 are arranged in an array along the second direction and the third direction, the plurality of word lines 300 are connected to the plurality of first conductive connection structures 302 in a one-to-one correspondence, and the third direction intersects with the second direction and the first direction.

The features disclosed in the several apparatus examples provided by the present disclosure may be arbitrarily combined without conflict to obtain a new apparatus example.

The method disclosed in the several method examples provided by the present disclosure may be arbitrarily combined without conflict to obtain a new method example.

The above descriptions are only specific implementations of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A semiconductor device, comprising:
a word line extending along a first direction;
a bit line extending along a second direction, wherein the second direction intersects with the first direction;
a first conductive connection structure located between a first surface and the word line, wherein an end of the first conductive connection structure is connected to the word line, and the first surface and a second surface are two surfaces of the semiconductor device opposite to each other along the first direction; and
a second conductive connection structure located between the second surface and the bit line, wherein an end of the second conductive connection structure is connected to the bit line.

2. The semiconductor device of claim 1, wherein:
the word line comprises a plurality of word lines, the first conductive connection structure comprises a plurality of first conductive connection structures, the plurality of word lines are arranged in an array along the second direction and a third direction, the plurality of word lines are connected to the plurality of first conductive connection structures in a one-to-one correspondence, and the third direction intersects with the second direction and the first direction, and
the semiconductor device further comprises a plurality of first conductive connection lines arranged along the second direction, wherein the first conductive connection lines extend along the third direction, and the first conductive connection lines are connected to a plurality of first conductive connection structures arranged along the third direction.

3. The semiconductor device of claim 2, comprising:
a plurality of memory blocks arranged along the third direction, wherein the first conductive connection lines are connected to the plurality of first conductive connection structures arranged along the third direction in the plurality of memory blocks.

4. The semiconductor device of claim 2, wherein the first conductive connection lines are located between the first conductive connection structure and the first surface.

5. The semiconductor device of claim 1, wherein along a direction perpendicular to the first direction, a size of an end of two opposite ends of the first conductive connection structure closer to the word line along the first direction is a first size; along the direction perpendicular to the first direction, a size of an end of two opposite ends of the first conductive connection structure farther from the word line along the first direction is a second size; and the first size is greater than the second size.

6. The semiconductor device of claim 1, wherein along a direction perpendicular to the first direction, a size of an end of two opposite ends of the first conductive connection structure closer to the word line along the first direction is a first size; along the direction perpendicular to the first direction, a size of an end of two opposite ends of the first conductive connection structure farther from the word line along the first direction is a second size; and the first size is smaller than the second size.

7. The semiconductor device of claim 2, further comprising:
a first bonding layer comprising a first bonding structure, wherein the first bonding layer is located on a side of two opposite sides of the word line along the first direction that is close to the second surface, and the first bonding structure is coupled to the word line and the bit line; and
a third conductive connection structure, wherein two ends of the third conductive connection structure are respectively connected to the first conductive connection line and the first bonding structure.

8. The semiconductor device of claim 2, comprising:
a memory layer comprising a plurality of word lines, a plurality of bit lines, and a plurality of memory cells, wherein:
the memory cell comprises a capacitor structure and a transistor structure arranged along the third direction;
the plurality of memory cells constitute a plurality of memory cell groups arranged along the third direction, the memory cell group comprises a plurality of memory cell subgroups arranged in an array along the first direction and the second direction, and the memory cell subgroup comprises a first memory cell and a second memory cell arranged along the third direction; and
one of the word lines is connected to the first memory cell or the second memory cell of the plurality of memory cell subgroups arranged along the first direction, and one of the bit lines is connected to the first memory cell and the second memory cell of the plurality of memory cell subgroups arranged along the second direction.

9. A memory device, comprising:
a first semiconductor structure and a second semiconductor structure stacked along a first direction, wherein the first semiconductor structure comprises a peripheral circuit, and the second semiconductor structure comprises:
a word line extending along the first direction;
a bit line extending along a second direction, wherein the second direction intersects with the first direction; and
a first conductive connection structure located on a side of two opposite sides of the word line along the first direction that is far from the first semiconductor structure, and an end of the first conductive connection structure is connected to the word line.

10. The memory device of claim 9, wherein the second semiconductor structure further comprises: a second conductive connection structure located between the bit line and the first semiconductor structure, wherein an end of the second conductive connection structure is connected to the bit line.

11. The memory device of claim 10, wherein the first semiconductor structure further comprises a second bonding layer, the second bonding layer comprises a second bonding structure, and the second bonding layer is located between the peripheral circuit and the second semiconductor structure; the second semiconductor structure further comprises a first bonding layer, the first bonding layer comprises a first bonding structure, and the first bonding layer is located between the first semiconductor structure and the word line or the bit line; and the second bonding structure is coupled to the peripheral circuit, the first bonding structure is coupled to the word line and the bit line, and the first bonding structure is connected to the second bonding structure.

12. The memory device of claim 11, wherein:
the word line comprises a plurality of word lines, the first conductive connection structure comprises a plurality of first conductive connection structures, the plurality of word lines are arranged in an array along the second direction and a third direction, the plurality of word lines are connected to the plurality of first conductive connection structures in a one-to-one correspondence, and the third direction intersects with the second direction and the first direction, and
the second semiconductor structure further comprises a plurality of first conductive connection lines arranged along the second direction, wherein the first conductive connection lines extend along the third direction, and the first conductive connection lines are connected to a plurality of first conductive connection structures arranged along the third direction.

13. The memory device of claim 12, wherein the second semiconductor structure comprises a plurality of memory blocks arranged along the third direction, and the first conductive connection lines are connected to the plurality of first conductive connection structures arranged along the third direction in the plurality of memory blocks.

14. The memory device of claim 12, wherein the first conductive connection line and the first bonding layer are respectively located on the two opposite sides of the word line along the first direction.

15. A method of manufacturing a semiconductor device, comprising:
forming a word line extending along a first direction;
forming a bit line extending along a second direction, wherein the second direction intersects with the first direction;
forming a first conductive connection structure located between a first surface and the word line, wherein an end of the first conductive connection structure is connected to the word line, and the first surface and a second surface are two surfaces of the semiconductor device opposite to each other along the first direction; and
forming a second conductive connection structure located between the second surface and the bit line, wherein an end of the second conductive connection structure is connected to the bit line.

16. The method of claim 15, wherein the word line comprises a plurality of word lines, the first conductive connection structure comprises a plurality of first conductive connection structures, the plurality of word lines are arranged in an array along the second direction and a third direction, the plurality of word lines are connected to the plurality of first conductive connection structures in a one-to-one correspondence, and the third direction intersects with the second direction and the first direction.

17. The method of claim 16, wherein the forming the word line, the bit line, the first conductive connection structure and the second conductive connection structure comprises:
providing a semiconductor layer comprising a first side and a second side opposite to each other along a thickness direction of the semiconductor layer;
forming the first conductive connection structure in the semiconductor layer from the first side;
forming the bit line and the word line on the semiconductor layer from the first side; and
forming the second conductive connection structure on the bit line from the first side.

18. The method of claim 17, further comprising:
before forming the first conductive connection structure in the semiconductor layer from the first side, forming a plurality of first conductive connection lines in the semiconductor layer from the first side, wherein the plurality of first conductive connection lines are arranged along the second direction, the first conductive connection lines extend along the third direction, and the first conductive connection lines are connected to a plurality of first conductive connection structures arranged along the third direction; and
wherein the forming the first conductive connection structure in the semiconductor layer from the first side comprises:
forming the first conductive connection structure on the first conductive connection line in the semiconductor layer from the first side.

19. The method of claim 16, wherein the forming the word line, the bit line, the first conductive connection structure and the second conductive connection structure comprises:
providing a semiconductor layer comprising a first side and a second side opposite to each other along a thickness direction of the semiconductor layer;
forming the bit line and the word line on the semiconductor layer from the first side;
forming the second conductive connection structure on the bit line from the first side;
thinning the semiconductor layer from the second side; and
forming the first conductive connection structure on the word line from the second side.

20. The method of claim 19, further comprising:
forming a plurality of first conductive connection lines on the first conductive connection structure from the second side, wherein the plurality of first conductive connection lines are arranged along the second direction, the first conductive connection lines extend along the third direction, and the first conductive connection lines are connected to a plurality of first conductive connection structures arranged along the third direction.
